(19) United States
(12) Patent Application Publication
(10) Pub. No.: US 2024/0123468 A1
(43) Pub. Date: Apr. 18, 2024

(54) Lumber Use Designation System And Method

(71) Applicant: Spectrum 28, LLC, Vestavia, AL (US)

(72) Inventor: R David Bonamy, JR., Birmingham, AL (US)

(73) Assignee: Spectrum 28, LLC, Vestavia, AL (US)

(21) Appl. No.: 18/397,145

(22) Filed: Dec. 27, 2023

Related U.S. Application Data
(63) Continuation-in-part of application No. 17/827,016, filed on May 27, 2022, now Pat. No. 11,878,326.
Application No. 17/827,016 is a continuation of application No. 17/015,867, filed on Sep. 9, 2020, now Pat. No. 11,383,276.
(60) Provisional application No. 62/900,007, filed on Sep. 13, 2019.

(51) Int. Cl. B07C 5/14; E04C 2/12; E04G 21/18; G06F 30/13

(52) U.S. Cl. CPC B07C 5/14; E04C 2/12; E04G 21/1891; G06F 30/13; G06Q 10/087

(57) ABSTRACT

A lumber use designation system includes a building construction plan that shows the layout of a structure and a coding from a series of codes each corresponding to a board length of lumber that should be selected for constructing a particular portion of the structure. A supply of lumber boards marked with a first board marking readable by an electronic scanner and a second board marking observable for selecting, which first and second board marking correlate to the board code found on the construction plans. The first board marking facilitates selecting a lumber board such as at a production facility. The second board marking facilitates selecting a lumber board at a job site for constructing the portion of the structure. A method of installing lumber during the construction of a structure is disclosed.

### CROSS REFERENCE TO RELATED APPLICATIONS

This application is a continuation-in-part of U.S. patent application Ser. No. 17/827,016 filed May 27, 2022, a continuation of U.S. patent application Ser. No. 17/015,867, filed Sep. 9, 2020, issued Jul. 12, 2022, as U.S. Pat. No. 11,383,276, with benefit of U.S. Provisional Patent Application No. 62/900,007 filed Sep. 13, 2019, entitled “Lumber Use Designation System”, and each is incorporated herein by reference.

### TECHNICAL FIELD

This invention relates to a system for efficiently selecting and utilizing lumber during the building process. More particularly, the present invention relates the designation and use of lumber to decrease waste.

### BACKGROUND OF THE INVENTION

Wood boards or lumber has been utilized for the building of physical structures for centuries. Today, lumber is available in many different sizes, such as 2″×4″, 4″×4″, 2″×6″, etc. These standard sized boards or lumber also come in a variety of standard longitudinal lengths, such as 8′, 10′, 12′, and 14′ lengths.

Prior to the construction process, construction plans or blueprints are made to show the height and location of each wall of the structure. During the construction process, carpenters follow these construction plans when forming the building walls, floor joists, ceiling joists, supports, rooflines, and other similar parts of the structure.

A problem commonly associated with the construction process relates to the large amount of lumber that is wasted during construction. One of the largest contributors to the generation of lumber waste stems from the fact that carpenters oftentimes utilize the first board he or she finds which is capable of completing the task, rather than taking the time and effort to find the best available appropriate board for the task. For example, if a construction plan calls for a 9 foot vertical wall, the carpenter may simply utilize the closest available board, even if that board is a 14 foot board. The carpenter then cuts the 14 foot board to 9 feet, resulting in the generation of 5 feet of board waste. This board waste however could have been reduced to only 1 foot of waste by the carpenter simply selecting a shorter 10 foot board rather than the longer 14 foot board. It is believed that a contributing factor to the generation of waste is due to the fact that once a board is in place, the original length of the board cannot be determined by a supervisor, as boards are typically marked only at the very end of the board. As such, there is no accountability on the part of the carpenter installing the boards as to the selection of the best fitting board. Further, lumber manufacturing and distribution facilities production increasingly rely on electronic sensor devices for tracking wood materials and boards produced at the facility and grouped for distribution to retailers and construction companies for building construction. There are drawbacks as color coding of the lumber may not reliably be determined correctly by electronic sensors.

Accordingly, there is a need in the art for an improved system of designating lumber in production facilities and in use for installing lumber to reduce the amount of wasted lumber during construction. It is to such that the present invention is directed.

### SUMMARY OF THE INVENTION

The present invention meets the need in the art by providing a lumber use designation system comprising a building construction plan illustrating a respective position of each of a plurality of building walls, each building wall displayed with a respective board code to indicate one of a plurality of board lengths of lumber, said respective board code designating the board length of lumber for use in constructing the respective coded building wall. A supply of lumber of the plurality of board lengths, each of the plurality of board lengths having one or more lumber each having a first board marking and a second board marking thereon. Each said first board marking and second board marking corresponding with said board code of said respective board length. Said one or more lumber for selecting by a scanner in a production facility based the first board marking and said one or more lumber for selecting by said second board marking at a job site for building the respective building wall illustrated on said construction plan, whereby the selected lumber of the respective board coding at the job site corresponds to the respective coded building wall in length or is cut shorter to length for constructing said respective building wall.

In another aspect, the present invention provides a lumber use designation system comprising a construction plan illustrating the position of a plurality of structure walls, each of the plurality of said illustrated structure walls including a respective board code of a plurality of board codes that indicates the length of lumber board to be used during the construction of the respective structure wall. A plurality of lumber boards and each one of the plurality of lumber boards having a first board marking and a second board marking thereon, said first board marking and said second board marking corresponds with a respective board code of said plurality of board codes of said building construction plan. A scanner operational in a lumber production facility for reading the first board marking for lumber production purposes and said second board marking for selecting a respective lumber at the job site corresponding to the respective coded building wall in length or is cut shorter to length for constructing said respective building wall.

In another aspect, the present invention provides a method of installing lumber during the construction of a structure, comprising the steps of:
(a) producing a construction plan illustrating a respective position of a plurality of structure walls, each of the plurality of the illustrated structure walls including a respective board code of a plurality of board codes that indicate a respective length of lumber board to be used during the construction of a respective one of the plurality of structure walls having said board code for the structure, wherein said board code designating a specific board length;
(b) providing a plurality of lumber boards each marked with a first board marking and a second board marking, said first board marking comprising a respective one of a plurality of board markings of a first type and said second board marking comprising a respective one of a plurality of board markings of a second type, said first board marking and second board marking corresponding to a respective one of the board codes of said building construction plan in accordance with a respective length of the lumber board for use in constructing a respective one of the structure walls;
(c) selecting the lumber boards within a lumber production facility with a scanner that reads the first board marking; and
(d) selecting the lumber boards at a job site to be installed during the construction of a respective one of the plurality of structure walls based on said second board marking by referencing the construction plan board code for said respective structure wall of the structure, whereby a one of the lumber boards having the second board code corresponding to the board code illustrated on the construction plan for the respective structure wall is selected, and
(e) installing the selected lumber board or cutting the selected lumber board to length for installing said cut selected lumber board to form said respective structure wall of the structure.

Objects, advantages and features of the present invention will be readily understood upon a reading of the following detailed description in conjunction with the drawings.

### BRIEF DESCRIPTION OF THE DRAWINGS

FIG. 1 shows a construction plan as an illustrative application of the lumber use designation system of the present invention.

FIG. 2 shows two stacks of lumber of the lumber use designation system of the present invention.

FIG. 3 shows a single board of lumber of the lumber use designation system of FIG. 2.

FIG. 4 is a schematic view of a paint head for the lumber use designation system of the present invention.

FIG. 5 is a schematic view of a lumber planar and paint head system for the lumber use designation system of the present invention.

FIG. 6 shows a single board of lumber of the lumber use designation system of the present invention.

FIG. 7 shows a single board of lumber in an alternate embodiment of the lumber use designation system of the present invention

### DETAILED DESCRIPTION

With reference next to the drawings, there is shown a lumber use designation system 10 as an illustrative application of the present invention. The system 10 includes a building construction plan or blueprint 12 which shows the layout, wall thickness, wall height, ceiling angles, etc., associated with a particular structure. The construction plan 12 illustrates or shows the location of building walls 14, and other structure specifications, which are color coded from a series of color codes. Each color in the series of color codes corresponds to a preselected, standard board size and length of lumber (type of board) that should be selected for constructing a correlated particular vertical wall structure or area of the wall. For example, the construction plan 12 may illustrate green walls 16 (green color board coded walls) to designate the use of green color coded or marked boards 18 for the construction of these walls 16, wherein the color green represents 2″ by 4″ (depth and width) boards having a longitudinal length of 10 feet. The construction plan 12 may have blue walls 20 (blue color board coded walls) to designate the use of blue color coded boards 22 used for the construction of these walls 20, wherein the color blue represents 2″ by 4″ boards having a longitudinal length of 12 feet. The construction plans may be board coded in a variety of manners which are easily printed upon the actual lumber boards, such as color codes, hash-markings, stripe-markings, alpha-numeric markings, or the like. However, it is believed that the color coding provides the best manner of marking a board as it is easy to recognize, is not language dependent, and stands out from other markings which may also appear on lumber, such as the manufacturer's name, batch number, etc.

The system 10 also includes a plurality of lumber boards that are imprinted or marked with a color code or coding correlating to the color code or coding found on the construction plans 12. FIG. 2 shows a first stack of lumber boards (first boards) 18 which have been imprinted with a first color coding, for example the color green. The first boards 18 have a longitudinal length of 10 feet. There is also shown a second stack of lumber boards (second boards) 22 which have been imprinted with a second color coding, for example the color blue. The second boards 22 have a longitudinal length of 12 feet.

The lumber boards may be imprinted with color coding in any conventional manner, such as by a conventional liquid spray head, liquid roller, of other device during or post manufacturing. The boards are printed with any conventional known marking media, such as an ink or paint, or may be marked by embossing, cutting into, etching, engraving or other manner of slightly disfiguring the surface of the board. Preferably, the boards are imprinted with several, spaced apart color coded strips 28 aligning in a lateral direction and completely surrounding each board, so that the mark may be observed with the board mounted in any position or orientation. Also, each board is marked in several locations to prevent the color coded stripe 28 from being lost due a portion of the board being cut off due to the board being shortened to a proper installation length.

Alternatively as illustrated in FIG. 6, the boards 50 may be marked with one or more longitudinally extending color coding stripes 52 extending the entire length of the board. Such a longitudinal stripe 52 would ensure that the board 50 contains the color stripe size designation no matter where the board is cut to length.

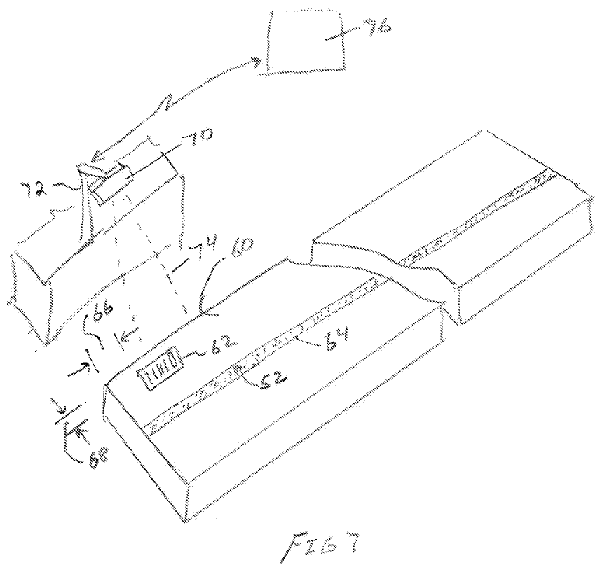

The board may be marked with the longitudinal stripe 52 by mounting a reciprocating belt 56 upon the exit end of a final board planar 58 which planes or finishes the board, as shown in FIG. 5. A multi-head paint sprayer 60 is coupled to the reciprocating belt 56. The multi-head paint sprayer 60 may include a paint supply line 61 and a pneumatic air or pressure line 62, as shown in FIG. 4. The paint sprayer 60 is coupled to a supply of paint or dye which is applied to the board in a manner that will not bleed onto other boards. Alternatively, the paint sprayer 60 may include multiple heads to spray different colors, a system to switch between one color and another color, or may simply require a different color paint to be introduced into the paint sprayer 60 when switching between colors. The reciprocating or back and forth action of the belt 56 produces the elongated stripe 52 upon the board 50. The operation of the paint spraying may be accomplished through sensors which sense the position of the board upon exiting the board planar 58.

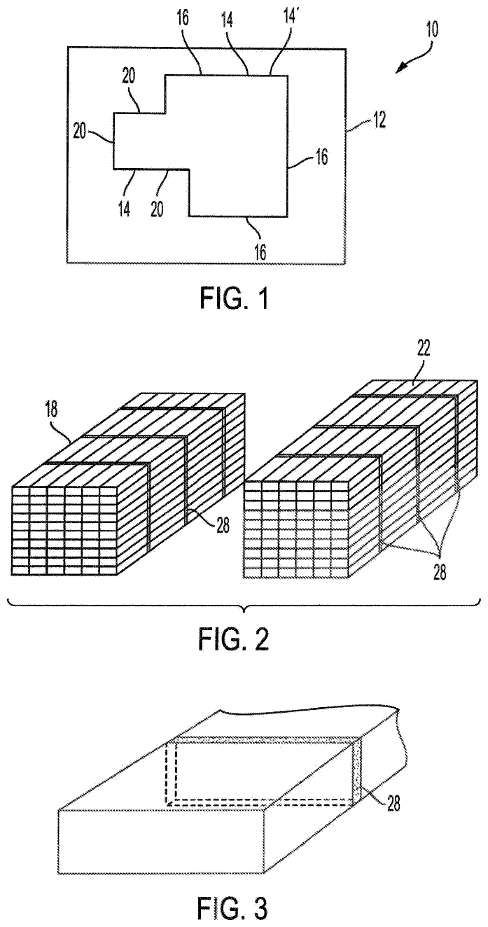

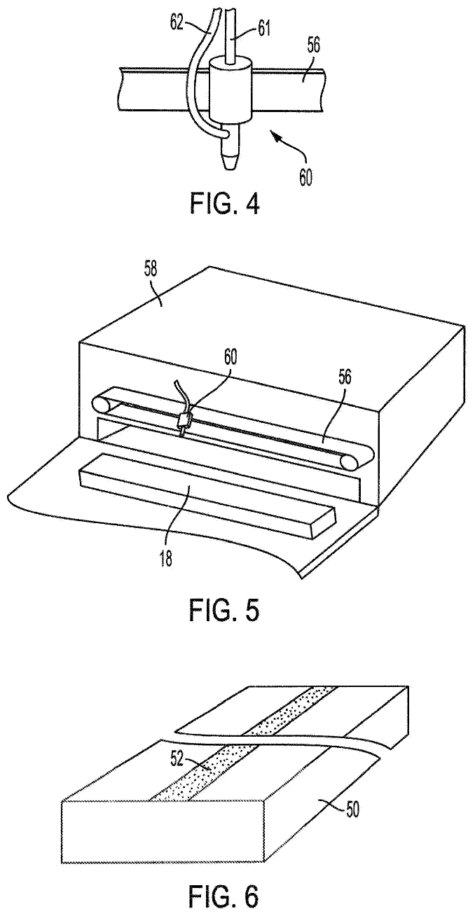

With reference to FIG. 1, in use of the system 10, the construction plans 12 are produced to include walls 14, or possibly other portions, that are color coded to reflect the length of board to be utilized during the construction process. Lumber or boards (for example, boards 18, 22) in accordance with the system 10 and construction plans 12 are delivered to the job site with the color coding that correlates with the construction plans 12.

A carpenter constructing the structure according to the plans 12 simply follows the system's color coding during the construction process. For example, when the time comes to build wall 14′ shown on construction plan 12, the carpenter notes that the plans 12 reflect that this is a green wall 16, i.e., the wall 14′ is color coded with the color green. The carpenter then selects one of the available green color coded boards 18, measures, and possibly cuts the board to the proper length. This color coding encourages the carpenter to use the proper preselected board length rather than cutting an unnecessarily longer (12 foot) blue color coded boards 22, which would be readily seen in an installed position by a supervisor as an error and a waste of lumber. As such, the green walls 16 of the construction plan 12 are constructed with green color coded boards 18, while the blue walls 20 are constructed with blue color coded boards 22.

While only two colors have been shown in the present example, it should be understood that any number of colors or other markings may be utilized to designed different lengths or sizes of boards. For example, while the previously described green and blue colors may be utilized for 2″×4″ boards, a different colors may be utilized for 2″×6″ sized boards of preselected lengths.

The distinct advantage to the invention described in the embodiment herein is that the color coding provides a post-installation inspection of the proper selection of board lengths during the construction process. Thus, there is a method of making the carpenter accountable for utilizing the most efficient board available, rather than simply the closest or first found board.

Another distinct advantage to the invention is that the color coding reduces the time and effort necessary to determine and locate the proper board for the task, as a size and length are previously determined and shown on the construction plans, and the color marking on the board is immediately recognizable from afar and eliminates the need to actually measure the board to determine if it is the best fit.

It is believed that with the standard color coding of all lumber, the amount of lumber waste could be greatly reduced.

It should be understood that as used herein, the term lumber or board includes boards made of any material, such as wood, metal, a composite, a laminate, or similar materials.

FIG. 7 illustrates an alternate embodiment of a lumber board 60 in the lumber use designation system 10 as an illustrative application of the present invention. The lumber board 60 features a first board marking 62 and the longitudinal stripe 52 as a second board marking 64. The first board marking 62 and the second board marking 64 both correspond with the board code of the respective board length. In the illustrated embodiment, the first board marking 62 is of a type different from the second board marking 64 that is based on the plurality of colors with each color associated with a respective board length. In the illustrated embodiment, the first board marking 62 is a coded symbol or identifier readily read or detected by an electronic scanner device, such as a bar code, or a hash-marking, stripe-marking, or alpha-numeric marking noted above. The first board marking 62 is a selected scanner-readable code, such as the illustrated bar code, which is a respective one of a plurality of bar codes each associated with a respective board length. In an alternate embodiment, the bar code may further indicate a particular board width and depth. In this embodiment, three distinct bar codes distinguish a board that is 8 feet long×12 inches wide×2 inch depth, a board that is 8 feet long×6 inches wide×2 inch depth, and a board that is 8 feet long×4 inches wide×2 inch depth.

Preferably the first board marking 62 is positioned in a predetermined relative location so that a fixed scanner device, fixed in position in a lumber production facility, readily locates and scans the first board marking. For example, the first board marking 62 may be positioned a selected distance 66 lateral of an end edge of the lumber board 60 and a selected distance 68 inwardly of a side edge of the lumber board.

FIG. 7 further illustrates an electronic sensor 70, for example, mounted to a support 72 in a production facility, such as a conveyor line for moving lumber boards 62 during processing and/or grouping with other the particular board type (length, width, depth, material grade) for processing, storage, and/or distribution. The sensor 70 scans 74 for the first board marking 62 and communicates the sensed first board marking to a control system 76 for directing the processing or handling of the lumber board 60.

The first board marking 62 enables the lumber board 60 to be scanned for selecting in a production facility based the first board marking. The second board marking 62 enables selecting the lumber board 60 at a job site for building the respective building wall illustrated on the construction plans, whereby the selected lumber of the respective board coding at the job site corresponds to the respective coded building wall in length or is cut shorter to length for constructing said respective building wall.

As discussed above, lumber marked in accordance with the invention may be selected by the first board marking 62 at a lumber production facility or, with a plurality of lumber at a job site, may be selected for use by the second board marking 64 during the construction of a building wall structure. To that end, the method comprises producing a construction plan illustrating a respective position of a plurality of structure walls, each of the plurality of the illustrated structure walls including a respective board code of a plurality of board codes that indicate a respective length of lumber board to be used during the construction of a respective one of the plurality of structure walls having said board code for the structure, wherein said board code designating a specific board length. Further, the method provides a plurality of lumber boards each marked with a first board marking and a second board marking. The first board marking comprising a respective one of a plurality of board markings of a first type and the second board marking comprising a respective one of a plurality of board markings of a second type. The first board marking and second board marking correspond to a respective one of the board codes of said building construction plan based on the board code associated with the respective length of the lumber board for use in constructing a respective one of the structure walls. The board markings enable selecting the lumber boards within a lumber production facility with a scanner that reads the first board marking and enable selecting the lumber boards at a job site to be installed during the construction of a respective one of the plurality of structure walls based on said second board marking by referencing the construction plan board code for said respective structure wall of the structure, whereby a one of the lumber boards having the second board code corresponding to the board code illustrated on the construction plan for the respective structure wall is selected. The wall is constructed by installing the selected lumber board or cutting the selected lumber board to length for installing the cut selected lumber board to form said respective structure wall of the structure.

It is to be appreciated that the board code of the construction plans is a respective one color code of a plurality of color codes, and the second board marking on a respective lumber board is a respective one color code of the plurality of color codes. Further, the first board marking comprises a respective one of a plurality of bar codes corresponding to the color code of the plurality of color codes.

This invention has been described with particular reference to certain illustrative embodiments, but variations and modifications can be made without departing from the spirit and scope of the invention. Variations of the lumber use designation system may fall within the spirit of the claims, below. It will be appreciated that the inventions are susceptible to modification, variation, and change without departing from the spirit thereof.

What is claimed is:

1. A lumber use designation system comprising:
a building construction plan illustrating a respective position of each of a plurality of building walls, each building wall displayed with a respective board code to indicate one of a plurality of board lengths of lumber, said respective board code designating the board length of lumber for use in constructing the respective coded building wall; and
a supply of lumber of the plurality of board lengths, each of the plurality of board lengths having one or more lumber each having a first board marking and a second board marking thereon, each said first board marking and second board marking corresponding with said board code of said respective board length, said one or more lumber for selecting by a scanner in a production facility based the first board marking and said one or more lumber for selecting by said second board marking at a job site for building the respective building wall illustrated on said construction plan, whereby the selected lumber of the respective board coding at the job site corresponds to the respective coded building wall in length or is cut shorter to length for constructing said respective building wall.

2. The lumber use designation system of claim 1 wherein said first board marking comprises a respective one bar code of a plurality of bar codes for reading by the scanner and wherein said second board marking is a respective one color of a plurality of colors.

3. The lumber use designation system of claim 1, wherein said first board marking is marked as a plurality of spaced-apart stripes to define a bar code.

4. The lumber use designation system of claim 1, wherein said board code further designates a specific board width and depth.

5. The lumber use designation system of claim 1, further comprising a paint sprayer for communicating with a supply of paint of each of the plurality of colors for said second board marking, said paint sprayer positioned relative to a lumber planer device configured for exiting lumber therefrom based on a scanner reading the first board marking, whereby a respective one of the plurality of colors for spraying the second board making on the respective length of lumber associated with the board code, whereby lumber exiting a board planer is marked by the paint sprayer with the respective board code.

6. The lumber use designation system of claim 5, further comprising a reciprocating belt to which the paint sprayer attaches, whereby the reciprocating belt moves the paint sprayer during spraying operation to apply the respective color to the exited lumber.

7. A lumber use designation system comprising:
a construction plan illustrating the position of a plurality of structure walls, each of the plurality of said illustrated structure walls including a respective board code of a plurality of board codes that indicates the length of lumber board to be used during the construction of the respective structure wall, and
a plurality of lumber boards and each one of the plurality of lumber boards having a first board marking and a second board marking thereon, said first board marking and said second board marking corresponds with a respective board code of said plurality of board codes of said building construction plan;
whereby a scanner operational in a lumber production facility for reading the first board marking for lumber production purposes and said second board marking for selecting a respective lumber at the job site corresponding to the respective coded building wall in length or is cut shorter to length for constructing said respective building wall.

8. The lumber use designation system of claim 7, wherein said first board marking comprises one of a plurality of bar codes and said second board marking comprises a respective one of a plurality of colors.

9. The lumber use designation system of claim 7, wherein said board code further designates a specific board width and depth.

10. A method of installing lumber during the construction of a structure, the method comprising the steps of:
(a) producing a construction plan illustrating a respective position of a plurality of structure walls, each of the plurality of the illustrated structure walls including a respective board code of a plurality of board codes that indicate a respective length of lumber board to be used during the construction of a respective one of the plurality of structure walls having said board code for the structure, wherein said board code designating a specific board length;
(b) providing a plurality of lumber boards each marked with a first board marking and a second board marking, said first board marking comprising a respective one of a plurality of board markings of a first type and said second board marking comprising a respective one of a plurality of board markings of a second type, said first board marking and second board marking corresponding to a respective one of the board codes of said building construction plan in accordance with a respective length of the lumber board for use in constructing a respective one of the structure walls;
(c) selecting the lumber boards within a lumber production facility with a scanner that reads the first board marking; and
(d) selecting the lumber boards at a job site to be installed during the construction of a respective one of the plurality of structure walls based on said second board marking by referencing the construction plan board code for said respective structure wall of the structure, whereby a one of the lumber boards having the second board code corresponding to the board code illustrated on the construction plan for the respective structure wall is selected, and
(e) installing the selected lumber board or cutting the selected lumber board to length for installing said cut selected lumber board to form said respective structure wall of the structure.

11. The method of installing lumber of claim 10, wherein the board code of the construction plans is a respective one color code of a plurality of color codes, and wherein the second board marking on a respective lumber board is a respective one color code of the plurality of color codes.

12. The method of installing lumber of claim 10, wherein the first board marking comprises a respective one of a plurality of bar codes.

13. The method of installing lumber of claim 10, further comprising the step of:
providing a paint sprayer for communicating with a supply of paint of each of the plurality of colors; and
selecting with a switch system one of the plurality of colors for spraying the second board marking on the respective lumber associated with the board code based on the first board marking,
whereby lumber exiting a board planer is marked with the respective second board marking.

14. The method of installing lumber of claim 13, further comprising the step of positioning said paint sprayer relative to a lumber planer device configured for exiting lumber therefrom, whereby lumber exiting the lumber planer is marked by the paint sprayer with the respective second board marking.

15. The method of installing lumber of claim 14, further comprising the step of attaching the paint sprayer to a reciprocating belt, whereby the reciprocating belt moves the paint sprayer during spraying operation to apply the respective color to the exited lumber.
